(19) United States
(12) Patent Application Publication
(10) Pub. No.: US 2013/0128418 A1
(43) Pub. Date: May 23, 2013

(54) Connecting Piece, Backplane, and LCD Device

(71) Applicants: Yicheng Kuo, Shenzhen (CN); Yuchun Hsiao, Shenzhen (CN); Chong Huang, Shenzhen (CN); Jiahe Cheng, Shenzhen (CN); Chengwen Que, Shenzhen (CN); Quan Li, Shenzhen (CN); Liuyang Yang, Shenzhen (CN)

(72) Inventors: Yicheng Kuo, Shenzhen (CN); Yuchun Hsiao, Shenzhen (CN); Chong Huang, Shenzhen (CN); Jiahe Cheng, Shenzhen (CN); Chengwen Que, Shenzhen (CN); Quan Li, Shenzhen (CN); Liuyang Yang, Shenzhen (CN)

(21) Appl. No.: 13/375,925

(22) PCT Filed: Nov. 29, 2011
(86) PCT No.: PCT/CN2011/083121

§ 371 Date: Dec. 2, 2011

(30) Foreign Application Priority Data
Nov. 18, 2011 (CN) 2011103695850

(51) Int. Cl. H05K 7/18; F16B 1/00; H05K 7/00

(52) U.S. Cl. 361/679.01; 24/591.1; 211/26

(57) ABSTRACT

The invention discloses a connecting piece, a backplane and an LCD device. A connecting piece of a frame type backplane, the connecting piece comprises at least two connecting parts which are respectively fixed with the end parts of brackets of the frame type backplane. In the invention, because the connecting piece is adopted for joining the brackets, the connecting piece can be made into an integrally formed structure with high strength for enhancing the joining strength of the brackets. Moreover, the connecting piece is provided with a plurality of connecting parts, each of which is individually connected with one bracket; an interface can achieve standards; the brackets can be made into standard sections and can also be cut according to various dimensions so that the universality of the brackets is enhanced.

### TECHNICAL FIELD

The invention relates to the field of liquid crystal displays, and more particularly to a connecting piece, a backplane, and a liquid crystal display (LCD) device.

### BACKGROUND

The LCD device includes an LCD panel and a backlight module, wherein the bottom of the backlight module is provided with a backplane used for sealing the module and fixing a component in the module. Conventional backplanes are integratedly formed using metal punching or plastic injection, with heavier products and higher material cost. For large-sized backplanes, because larger punching equipment is needed, the cost is higher, the corresponding die dimension is very large, the structure is complicated, and the die cost is also very high. With increasingly fierce market competition, it is more and more important to effectively reduce the design cost. As a result, the key research direction for each designer lies in saving the material cost and simplifying the packaging technology.

In a new backplane, the design of hollowing or joining the backplane is developed on the integral design of the backplane; the cost is reduced to a certain extent; however, the joining or hollowing reduces the strength of the backplane, so that it is difficult to originally fix a PCB on the backplane.

### SUMMARY

The aim of the invention is to provide a connecting piece with high connection strength for enhancing the universality of brackets, a backplane, and an LCD device.

The purpose of the invention is achieved by the following technical schemes.

A connecting piece for a frame type backplane, the connecting piece comprises at least two connecting parts respectively fixed with end parts of brackets of the frame type backplane.

Preferably, there are two connecting parts which are mutually vertical; one end of each connecting part is fixedly connected. It is a structural form of an angular connector, which is used for fixing two brackets at four angular positions of the frame.

Preferably, there are two connecting parts which are in the same straight line; one end of each connecting part is fixedly connected. It is a straight connecting piece, which is used for joining two short brackets into a long bracket.

Preferably, there are three connecting parts; two of the connecting parts are in the same straight line and are mutually vertical with the other connecting part; one end of each of the three connecting parts is fixedly connected. It is a three-way connecting piece, which can achieve the overlapping of a new bracket in the middle of the frame.

Preferably, the connecting parts are provided with reinforcing ribs for enhancing the strength of the connecting piece.

Preferably, the reinforcing ribs among the connecting parts intersect; the intersected reinforcing ribs can strengthen the strength of the joining positions of different connecting parts.

Preferably, the connecting parts comprise two mutually opposite laminates; the brackets are embedded between the two laminates and fixed. It is a double-layered connecting piece. The brackets can be fixed from both sides thereof, with higher connection strength.

Preferably, the connecting parts are provided with one laminate; the brackets and the laminate are superposed and fixed. It is a single-layered connecting piece, which can save the material of the connecting piece and reduce the cost.

The invention further provides a frame type backplane for a backlight module. The frame type backplane comprises a frame; the frame comprises a plurality of mutually joined brackets; the frame on joining positions of the brackets is provided with the connecting piece for the frame type backplane.

Preferably, the connecting parts comprise two mutually opposite laminates which form installing grooves; the brackets are embedded into the installing grooves and fixed; the brackets connected with the connecting piece are not in contact with each other; one end of the installing grooves connected with the connecting parts is a solid structure, namely the installing grooves of the two connecting parts are not communicated with each other. It is a double-layered connecting piece. The brackets can be fixed from both sides thereof, with higher connection strength. Moreover, that one end connected with the connecting parts is a solid structure can enhance the strength of the connecting position.

Preferably, the connecting parts comprise two mutually opposite laminates which form installing grooves; the brackets are embedded into the installing grooves and fixed; the brackets connected with the connecting piece are not in contact with each other; one end of the installing grooves connected with the connecting parts is a hollow structure, namely the installing grooves of the two connecting parts are communicated with each other. It is another double-layered connecting piece. The brackets can be fixed from both sides thereof, with higher connection strength. One end connected with the connecting parts is hollow, which is convenient for superposing and fixing the two brackets in the connecting piece so as to further enhance the joining strength.

Preferably, the connecting parts are provided with one laminate; the brackets and the laminate are superposed and fixed.

Preferably, one end of each bracket in the joining position is superposed and is fixedly connected with the connecting piece. It is a single-layered connecting piece, which can save the material of the connecting piece and reduce the cost.

Preferably, the brackets and the connecting piece are fixed in one or more modes of riveting, screwed connection, latch connection, and bond master bonding. It is a specific fixing form among the brackets and the connecting piece.

An LCD device comprises the frame type backplane of the backlight module.

In the invention, because the connecting piece is employed to join the brackets, the connecting piece can be made into an integratedly formed structure with high strength, thereby enhancing the joining strength of the brackets. Moreover, generally, reinforcing ribs are arranged on the brackets; if two brackets are directly joined, one bracket is provided with a corresponding groove in the joining position to form an “L” reinforcing rib so as not to increase the thickness of the joining position in joining the two brackets; in this way, the reinforcing rib of the other bracket can be embedded into the groove so that the thickness of the joining position is not obviously increased; however, in the mode, the corresponding bracket must be made in advance according to different dimensions of the backplanes, thereby causing poor universality. The connecting piece in the invention has a plurality of connecting parts, each of which is individually connected with one bracket; thus, an interface is universal; the brackets can be made into standard sections and can also be cut according to various dimensions to enhance the universality of the brackets.

### BRIEF DESCRIPTION OF FIGURES

FIG. 1 is a schematic diagram of a frame type backplane;

FIG. 2 is a schematic diagram of a frame type backplane with a connecting piece;

FIG. 3 is a schematic diagram of a first connecting piece in the example of the invention;

FIG. 4 is a schematic diagram of a second connecting piece in the example of the invention;

FIG. 5 is a schematic diagram of a third connecting piece in the example of the invention;

FIG. 6 is a schematic diagram of joining two brackets through a connecting piece in the example of the invention;

FIG. 7 is another schematic diagram of joining two brackets through a connecting piece in another example of the invention;

FIG. 8 is a schematic diagram of a double-layered connecting piece in the example of the invention;

Legends: 100. frame; 110. bracket; 111. upper bracket; 112. right bracket; 113. lower bracket; 114. left bracket; 115. middle bracket; 120. bridge; 130. connecting piece; 131. connecting part; 132. laminate; 133. installing groove; 134. reinforcing rib.

### DETAILED DESCRIPTION

The invention will further be described in detail in accordance with the figures and the preferred examples.

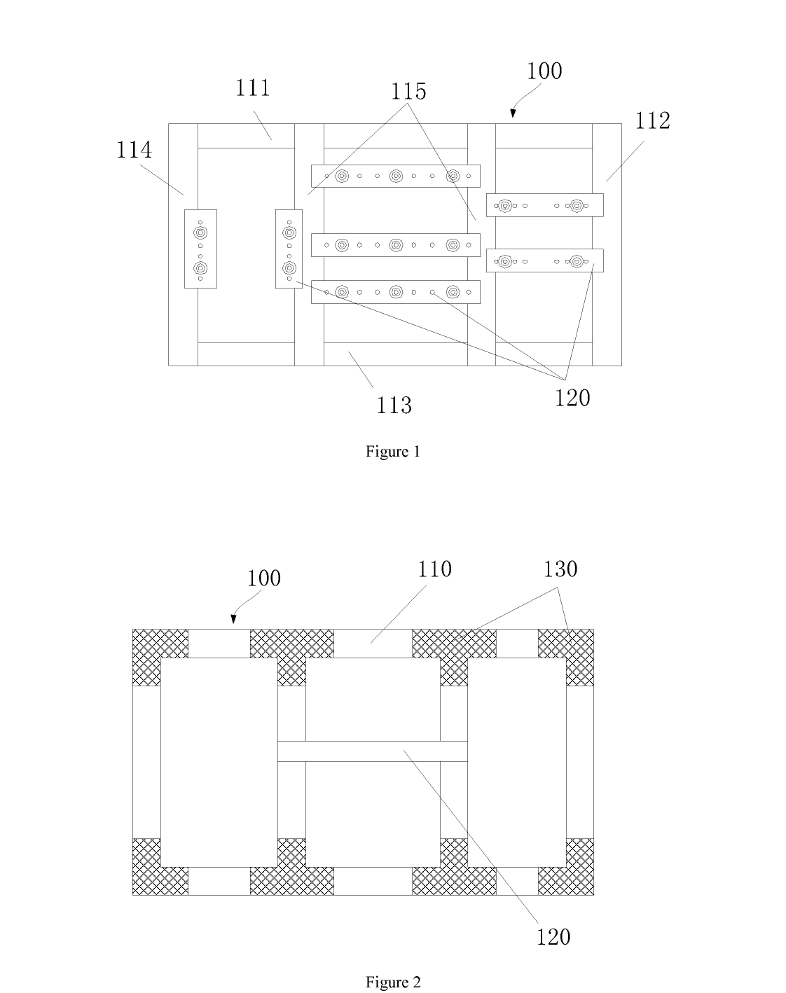

An LCD device comprises an LCD panel and a backlight module. The bottom of the backlight module is provided with a backplane. The backplane comprises a frame 100 which comprises a plurality of brackets 110. The frame 100 is provided with a plurality of bridges 120. As shown in FIG. 1, the brackets 110 comprise an upper bracket 111, a lower bracket 113, a left bracket 114, and a right bracket 112 which are placed end to end to form a large frame 100 of the whole backplane. The large frame 100 is further internally provided with two middle brackets 115; both ends of the middle brackets 115 are respectively fixed to the upper and the lower brackets 110. A plurality of bridges 120 are arranged on each bracket 110 and between the two brackets 110. The bridges 120 can fix the PCB and other components of the backlight module.

The upper brackets 111 of the backplane are joined through a connecting piece 130 which comprises at least two connecting parts 131 which are respectively fixed with the end parts of the brackets 110 of the frame 100 type backplane.

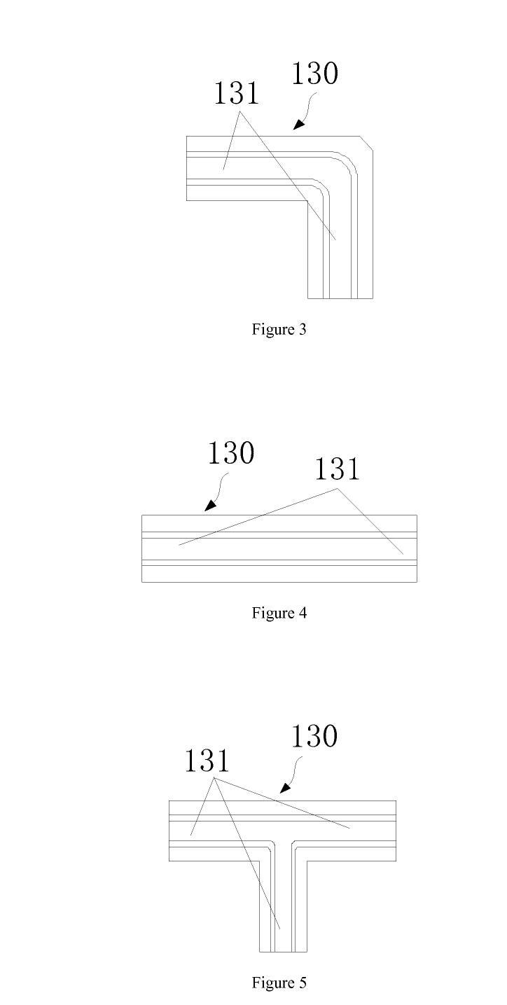

As shown in FIG. 3, the connecting piece 130 can be made into a form of angular connection, namely the connecting piece 130 has two connecting parts 131 which are mutually vertical; one end of each connecting part 131 is fixedly connected. The connecting piece 130 can be used for connecting and fixing two brackets 110 at four angular positions of the frame 100.

As shown in FIG. 4, a straight connecting piece 130 is used for joining two short brackets 110 into a long bracket 110. The connecting piece has two connecting parts 131 which are in the same straight line; one end of each connecting part 131 is fixedly connected.

As shown in FIG. 5, a three-way connecting piece 130 can achieve the overlapping of a new bracket 110 in the middle of the frame 100. The connecting piece has three connecting parts 131; two of the connecting parts 131 are in the same straight line and are mutually vertical with the other connecting part 131; one end of the three connecting parts 131 is fixedly connected.

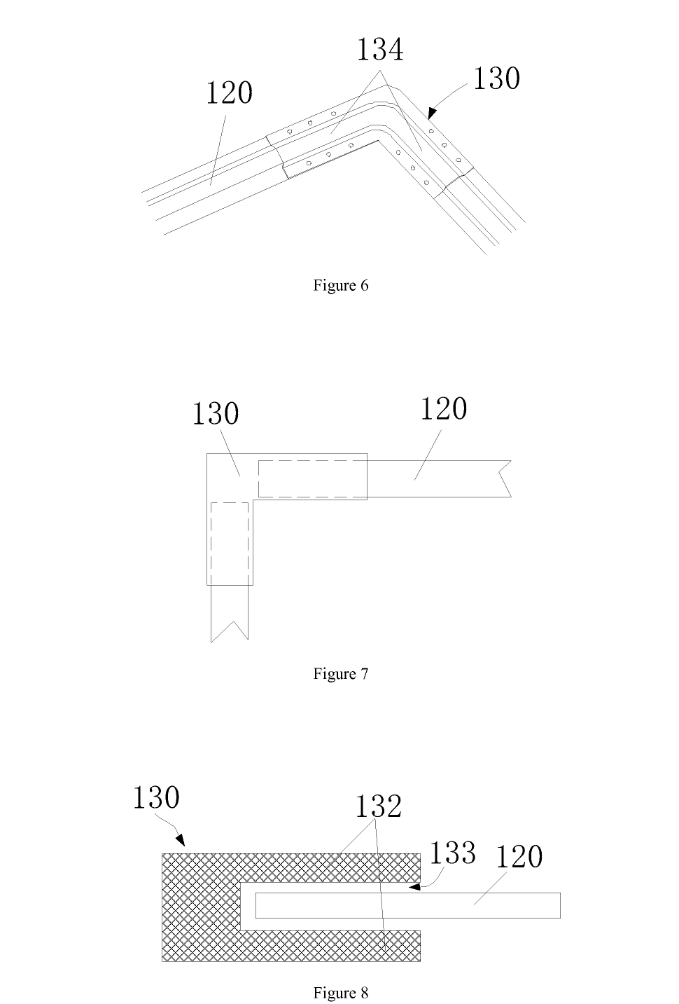

As shown in FIG. 6, the connecting parts 131 can be provided with reinforcing ribs 134 for enhancing the strength of the connecting piece 130. The reinforcing ribs 134 among the connecting parts 131 intersect; the intersected reinforcing ribs 134 can strengthen the strength of the joining positions of different connecting parts 131.

As shown in FIG. 7 and FIG. 8, the connecting piece 130 can be a double-layered structure. The brackets 110 can be fixed on both sides thereof, with higher connection strength. The connecting parts 131 of the connecting piece 130 comprise two mutually opposite laminates 132 to form installing grooves 133; the brackets are embedded into the installing grooves 133 and fixed; the brackets 110 connected with the connecting piece 130 are not in contact with each other; one end of the installing grooves 133 connected with the connecting parts 131 is a solid structure, namely the installing grooves 133 of the two connecting parts 131 are not communicated with each other. Optionally, one end of the installing grooves 133 connected with the connecting parts 131 can be a hollow structure, namely the installing grooves 133 of the two connecting parts 131 are communicated, which is convenient for superposing and fixing the two brackets 110 in the connecting piece 130, so as to further enhance the joining strength.

The connecting piece 130 can be a single-layered structure for saving the material of the connecting piece 130 and reducing the cost. The connecting parts 131 are provided with one laminate 132; the brackets 110 and the laminate 132 are superposed and fixed. One end of each bracket 110 in the joining position is superposed and fixed, namely the fixed connection is conducted between brackets 110 and among the brackets 110 and the connecting piece 130, so as to further enhance the joining strength.

In a specific fixed mode, the brackets 110 and the connecting piece 130 are fixed in one or more modes of riveting, screwed connection, latch connection, and bond master bonding.

The invention is described in detail in accordance with the above contents with the specific preferred examples. However, this invention is not limited to the specific examples. For the ordinary technical personnel of the technical field of the invention, on the premise of keeping the conception of the invention, the technical personnel can also make simple deductions or replacements, and all of which should be considered to belong to the protection scope of the invention.

We claim:

1. A connecting piece of a frame type backplane, comprising: at least two connecting parts which are respectively fixed with end parts of brackets of said frame type backplane.

2. A connecting piece of the frame type backplane of claim 1, wherein there are two connecting parts which are mutually vertical; one end of each connecting part is fixedly connected.

3. A connecting piece of the frame type backplane of claim 1, wherein there are two connecting parts which are in the same straight line; one end of each connecting part is fixedly connected.

4. A connecting piece of the frame type backplane of claim 1, wherein there are three connecting parts; two of the connecting parts are in the same straight line and are mutually vertical with the other connecting part; one end of each of said three connecting parts is fixedly connected.

5. The connecting piece of the frame type backplane of claim 1, wherein said connecting parts are provided with reinforcing ribs.

6. The connecting piece of the frame type backplane of claim 5, wherein said reinforcing ribs among the connecting parts intersect.

7. The connecting piece of the frame type backplane of claim 1, wherein said connecting parts comprise two mutually opposite laminates; said brackets are embedded between the two laminates and fixed.

8. The connecting piece of the frame type backplane of claim 1, wherein said connecting parts are provided with one laminate; said brackets and said laminate are superposed and fixed.

9. A frame type backplane of a backlight module, comprising: a frame; said frame comprises a plurality of mutually joined brackets; said frame in the joining positions of the brackets is provided with the connecting piece of the frame type backplane of claim 1; said connecting piece of the frame type backplane comprises at least two connecting parts which are respectively fixed with the end parts of the bracket of the frame type backplane.

10. The frame type backplane of the backlight module of claim 9, wherein there are two connecting parts which are mutually vertical; one end of each connecting part is fixedly connected.

11. The frame type backplane of the backlight module of claim 9, wherein there are two connecting parts which are in the same straight line; one end of each connecting part is fixedly connected.

12. The frame type backplane of the backlight module of claim 9, wherein there are three connecting parts; two of the connecting parts are in the same straight line and are mutually vertical with the other connecting part; one end of each of said three connecting parts is fixedly connected.

13. The frame type backplane of the backlight module of claim 9, wherein said connecting parts are provided with reinforcing ribs.

14. The frame type backplane of the backlight module of claim 13, wherein said reinforcing ribs among the connecting parts intersect.

15. The frame type backplane of the backlight module of claim 9, wherein said connecting parts comprise two mutually opposite laminates; said brackets are embedded between the two laminates and fixed.

16. The frame type backplane of the backlight module of claim 9, wherein said connecting parts are provided with one laminate; said brackets and said laminate are superposed and fixed.

17. The frame type backplane of the backlight module of claim 9, wherein said connecting parts comprise two mutually opposite laminates to form installing grooves; said brackets are embedded into the installing grooves and fixed; the brackets connected with said connecting piece are not in contact with each other; one end of said installing grooves connected with the connecting parts is a solid structure, namely the installing grooves of the two connecting parts are not communicated with each other.

18. The frame type backplane of the backlight module of claim 9, wherein said connecting parts comprise two mutually opposite laminates to form installing grooves; said brackets are embedded into the installing grooves and fixed; the brackets connected with said connecting piece are not in contact with each other; one end of said installing grooves connected with the connecting parts is a hollow structure, namely the installing grooves of the two connecting parts are communicated with each other.

19. The frame type backplane of the backlight module of claim 9, wherein said connecting parts are provided with one laminate; said brackets and said laminate are superposed and fixed.

20. The frame type backplane of the backlight module of claim 9, wherein said brackets on one end of the joining positions are superposed and fixedly connected with said connecting piece.

21. The frame type backplane of the backlight module of claim 9, wherein said brackets and said connecting piece are fixed in one or more modes of riveting, screwed connection, latch connection, and bond master bonding.

22. An LCD device, comprising: the frame type backplane of the backlight module of claim 9; said frame type backplane of the backlight module comprises a frame which comprises a plurality of mutually joined brackets; and said frame is provided with the connecting piece of the frame type backplane in the joining positions of said brackets; said connecting piece of the frame type backplane comprises at least two connecting parts which are respectively fixed with the end parts of the bracket of the frame type backplane.

23. The LCD device of claim 22, wherein there are two connecting parts which are mutually vertical; one end of each connecting part is fixedly connected.

24. The LCD device of claim 22, wherein there are two connecting parts which are in the same straight line; one end of each connecting part is fixedly connected.

25. The frame type backplane of the backlight module of claim 22, wherein there are three connecting parts; two of the connecting parts are in the same straight line and are mutually vertical with the other connecting part; and one end of each of said three connecting parts is fixedly connected.

26. The LCD device of claim 22, wherein said connecting parts are provided with reinforcing ribs.

27. The LCD device of claim 26, wherein said reinforcing ribs among the connecting parts intersect.

28. The LCD device of claim 22, wherein said connecting parts comprise two mutually opposite laminates; and said brackets are embedded between the two laminates and fixed.

29. The LCD device of claim 22, wherein said connecting parts are provided with one laminate; and said brackets and the laminate are superposed and fixed.
